(19) United States
(12) Patent Application Publication
(10) Pub. No.: US 2003/0197288 A1
(43) Pub. Date: Oct. 23, 2003

(54) Reduced stress wire bond

(75) Inventor: Ephraim Suhir, Los Altos, CA (US)

Correspondence Address: SCHNADER HARRISON SEGAL & LEWIS, LLP, 1600 MARKET STREET, SUITE 3600, PHILADELPHIA, PA, 19103

(73) Assignee: LUCENT TECHNOLOGIES INC., MURRAY HILL, NJ

(21) Appl. No.: 10/126,124

(22) Filed: Apr. 19, 2002

(51) Int. Cl. H01L 23/48; H01L 29/40; H01L 21/50

(52) U.S. Cl. 257/784; 438/617; 257/786; 438/612; 257/669; 438/123

(57) ABSTRACT

A wire bond comprising an intentionally introduced ends offset wherein the ends offset reduces stress from axial displacement as compared to the same axial displacement on a wire bond without an intentionally introduced ends offset. Further disclosed are a semiconductor device comprising at least one wire bond having an intentionally introduced stress reducing ends offset, and methods for fabricating a wire bond and semiconductor device.

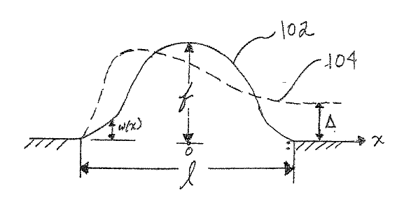

### FIELD OF THE INVENTION

The invention relates to wire bonding in semiconductor devices, and more particularly to reduced stress in wire bonds.

### BACKGROUND OF THE INVENTION

Wire bonding is a method by which very fine wires are attached to semiconductor components for connection of those components with each other or with package leads. The term “wire bond” is often used to identify the wire portion of the bond, and will be used as such herein.

When a wire bond fixed at both ends is subjected to temperature variations or other stresses, the ends may become offset with respect to an initial line drawn between the two end points of the wire. It is a general perception that this ends offset is an unfavorable effect on the maximum stress in a wire bond subjected to axial displacement. Therefore, engineers try to minimize the ends offset, or at least to add the stress due to such an offset to the stress caused by axial displacement, whether in tension or compression.

It has been previously believed that ends offset, in most cases may lead to weakening or failure in a device in which it occurs. Accordingly, efforts have been made to eliminate or reduce ends offset.

### SUMMARY OF THE INVENTION

The present invention is based on the realization that ends offset is not necessarily an unfavorable effect. Not only may an ends offset that naturally occurs from a traditional design or manufacturing process reduce stress, but an ends offset even greater than what naturally occurs may reduce stress further.

In accordance with principles of the invention, a wire bond has intentionally introduced ends offset, wherein the ends offset reduces stress from axial displacement as compared to the same axial displacement on a wire bond without intentionally introduced ends offset. This reduction in stress may enhance device performance and reduce device failure.

Further disclosed are a semiconductor device comprising at least one wire bond having a stress reducing intentionally introduced ends offset, and methods for fabricating a wire bond and semiconductor device.

### DESCRIPTION OF THE DRAWING

The invention is best understood from the following detailed description when read with the accompanying drawing.

The Figure depicts a wire bond with and without an ends offset.

### DETAILED DESCRIPTION OF THE INVENTION

The present invention is based on the realization that ends offset is not necessarily an unfavorable effect. In many situations an ends offset may lead to a stress relief in postbuckling bending stresses due to axial compression in a wire bond, as compared to additional bending stress caused by the ends offset.

The figure depicts a wire bond without an ends offset 102, and the wire bond experiencing post-buckling bending 104 and having an offset Δ. Typically, the wire bond span l is small and its maximum deflection ƒ is appreciable. For example, l=0.5 mm and ƒ=0.2 mm. Such a configuration, from a structural analysis viewpoint, can be treated as a configuration of a beam subjected to a significant compressive force, exceeding the buckling, or Euler force. A wire bond in its post-buckling mode may or may not experience an offset of its ends. Although an ends offset results in an additional bending moment in the wire, which is usually an unfavorable effect, it reduces the curvatures or bending moments caused by the compressive force, which is typically a favorable effect. In the analysis that follows, it is demonstrated that the favorable effect of the ends offset is prevailing, and therefore, the deliberate application of the wire ends offset can be employed advantageously to lower the high stresses due to post-buckling bending.

The configuration of the wire bond subjected to post-buckling bending and experiencing ends offset as depicted in the figure, can be sought in the form:

$$w ( x ) = {C}_{o} + {C}_{2} cos k x + \frac{Δ}{2} ( 1 + 3 \frac{x}{l} - 4 \frac{{x}^{3}}{{l}^{3}} ) \qquad ( 1 )$$

where Δ is the ends offset, l is the wire span (distance between the bonded ends and the post-buckling condition), C₀ and C₂ are constants of integrating the equation

$${w}^{i v} + {k}^{2} w = 0 , k = \sqrt{\frac{T}{EI}} \qquad ( 2 )$$

of bending, T is the compressive force, and EI is the flexural rigidity of the wire. The last term in Equation (1) is the initial (compression free) curvature of the wire, and the first two terms reflect the additional deflections due to buckling. The boundary conditions

$$\begin{matrix}w ( - \frac{l}{2} ) = 0 , w ( \frac{l}{2} ) = Δ , {w}^{′} ( \pm \frac{l}{2} ) = 2 & ( 3 ) \\ yield : {C}_{2} = {C}_{0} , sin = \frac{k l}{2} = 0 & ( 4 )\end{matrix}$$

The second formula in Equation (4) results in the following expression for the κ value:

$$k = \frac{2 π}{l} \qquad ( 5 )$$

This formula and the second formula in Equation (2) result in the following formula for the compressive force:

$$T = \frac{4 {π}^{2} E I}{{l}^{2}} \qquad ( 6 )$$

This is the well-known formula for the buckling (Euler) force for a beam clamped at both ends with no ends offset. The obtained result indicates that the ends offset does not change the magnitude of the buckling force. Only the prebuckling mechanical behavior of the wire is different: a beam with no ends offset remains straight up to the very moment of buckling, while the deflections of the beam with ends offset change gradually, when the compressive force changes from zero to its critical (buckling) value.

The elastic curve expressed by Equation (1), considering the first relationship in equation (4) and the Formula (5), is:

$$w ( x ) = {C}_{0} ( 1 + cos \frac{2 π x}{l} ) + \frac{Δ}{2} ( 1 + 3 \frac{x}{l} - 4 \frac{{x}^{3}}{{l}^{3}} ) \qquad ( 7 )$$

The constant C₀ and the location x=x* of the maximum deflection Wₘₐₓ−ƒ of the wire can be found from the equations:

$$\begin{matrix}{w}^{′} ( {x}_{*} ) = - \frac{2 π}{l} {C}_{0} sin \frac{2 π {x}_{*}}{l} + \frac{3 Δ}{2 l} [ 1 - {( \frac{2 {x}_{*}}{l} )}^{2} ] = 0 & ( 8 a ) \\ w ( {x}_{*} ) = {C}_{0} ( 1 + cos \frac{2 π {x}_{*}}{l} ) + \frac{Δ}{2} ( 1 + 3 \frac{{x}_{*}}{l} - 4 \frac{{x}_{*}^{3}}{{l}^{3}} ) = f & ( 8 b )\end{matrix}$$

which yield:

$$\begin{matrix}\frac{Δ}{f} = 2 {\{ 1 + \frac{{x}_{*}}{l} [ 3 - {( \frac{2 {x}_{*}}{l} )}^{2} ] + \frac{3}{2 π} [ 1 - {( \frac{2 {x}_{*}}{l} )}^{2} ] cotan \frac{ π {x}_{*}}{l} \}}^{- 1} & ( 9 a ) \\ \frac{{C}_{0}}{f} = \frac{3}{4 π} \frac{Δ}{f} \frac{1 - {( \frac{2 {x}_{*}}{l} )}^{2}}{sin \frac{2 π {x}_{*}}{l}} & ( 9 b )\end{matrix}$$

Equation (8a) defines the location x=x* of the maximum value of the deflection function w(x). Equation (8b) defines the magnitude of this maximum. The calculated Δ/ƒ and C₀/ƒ ratios are shown in the following table:

| | | | | | | |
|---|---|---|---|---|---|---|
| 2x*/l | 0 | 0.01 | 0.05 | 0.10 | 0.30 | 0.5 |
| Δ/f | 0 | 0.06368 | 0.28064 | 0.48380 | 0.87365 | 0.97771 |
| C₀/f | 0.5 | 0.48396 | 0.42721 | 0.37002 | 0.23460 | 0.17506 |
| χ | 1 | 0.98728 | 0.93973 | 0.88710 | 0.73476 | 0.64730 |

The χ value is the ratio of the maximum curvature:

$${κ}_{max} = {w}^{″} ( - \frac{l}{2} ) = {( \frac{2 π}{l} )}^{2} {C}_{0} + \frac{6 Δ}{{l}^{2}} \qquad ( 10 )$$

of a wire, experiencing ends offset, to the maximum curvature:

$${κ}_{max} = 2 {π}^{2} \frac{f}{{l}^{2}} \qquad ( 11 )$$

of the same wire, but with no ends offset. As evident from the computed data, a significant stress relief can be expected, if the ends offset is introduced. Accordingly, there is no need to “fight” the ends offset, if it comes out naturally because of the “short comings” of a particular wire bonding or packaging technology. It may also be intentionally introduced into the wire bond.

Embodiments of the invention provide a wire bond having intentionally introduced ends offset wherein the ends offset reduces stress from axial displacement as compared to the same axial displacement on a wire bond without intentionally introduced ends offset. In an illustrative embodiment of the invention, the ratio of the maximum curvature of the wire bond with intentionally introduced ends offset, to the maximum curvature of the wire bond without intentionally introduced ends offset is less than about 0.95. In a further embodiment of the invention, the ratio is less than about 0.65. In yet another embodiment the ratio is in the range of about 0.60 to about 0.95.

Further affecting the relative stress is the ratio of the offset to the maximum deflection. An illustrative range of the offset to maximum deflection ratio is about 0.10 to about 0.50.

Further disclosed are a semiconductor device comprising at least one wire bond having intentionally introduced ends offset which reduces stress from axial displacement, and methods of fabricating a wire bond and semiconductor device by intentionally providing stress reducing ends offset.

While the invention has been described by illustrative embodiments, additional advantages and modifications will occur to those skilled in the art. Therefore, the invention in its broader aspects is not limited to specific details shown and described herein. Modifications, for example, to the curvature and ends offset of the wire bond, or the derivation of the stress relief or nds offset, may be made without departing from the spirit and scope of the invention. Accordingly, it is intended that the invention not be limited to the specific illustrative embodiments, but be interpreted within the full spirit and scope of the appended claims and their equivalents.

1. A wire bond comprising intentionally introduced ends offset wherein the ends offset reduces stress from axial displacement as compared to the same axial displacement on a wire bond without intentionally introduced ends offset.

2. The wire bond of claim 1 wherein the ratio of the maximum curvature of the wire bond with ends offset, to the maximum curvature of the wire bond without ends offset is less than about 0.95.

3. The wire bond of claim 2 wherein the ratio is in the range of about 0.60 to about 0.95.

4. The wire bond of claim 1 wherein the ratio of the offset to the maximum deflection is in the range of about 0.10 to about 0.50.

5. A semiconductor device comprising at least one wire bond according to claim 1.

6. A method of fabricating a wire bond wherein the wire bond has two ends, the method comprising:
intentionally offsetting the ends so that stress from axial displacement is reduced as compared to the same axial displacement on a wire bond without an intentionally introduced ends offset.

7. The method of claim 6 wherein the ratio of the maximum curvature of the wire bond with ends offset, to the maximum curvature of the wire bond without ends offset is less than about 0.95.

8. The method of claim 7 wherein the ratio is in the range of about 0.60 to about 0.95.

9. The method of claim 6 wherein the ratio of the offset to the maximum deflection is in the range of about 0.10 to about 0.50.

10. A method of fabricating a semiconductor device comprising at least one wire bond wherein the wire bond has two ends, the method comprising:
intentionally offsetting the ends so that stress from axial displacement is reduced as compared to the same axial displacement on a wire bond without an intentionally introduced ends offset.
